(19) United States
(12) Patent Application Publication
(10) Pub. No.: US 2011/0241754 A1
(43) Pub. Date: Oct. 6, 2011

(54) LEVEL SHIFTER AND METHOD OF CONTROLLING LEVEL SHIFTER

(75) Inventor: Kiichi Kajino, Hara-mura (JP)

(73) Assignee: Seiko Epson Corporation, Tokyo (JP)

(21) Appl. No.: 13/075,392

(22) Filed: Mar. 30, 2011

(30) Foreign Application Priority Data
Apr. 2, 2010 (JP) 2010-086311

(51) Int. Cl. H03L 5/00

(52) U.S. Cl. 327/333

(57) ABSTRACT

A level shifter converts an input signal changing between a first potential level and a second potential level into an output signal changing between the first potential level and a third potential level. The level shifter includes: a first circuit configured to be able to hold a potential at an input terminal to which the input signal is input at the first potential level; and a second circuit configured to be able to hold a potential at an output terminal from which the output signal is output at the first potential level.

### BACKGROUND

1. Technical Field

An aspect of the invention relates to a level shifter, and more particularly to a level shifter configured to be able to hold terminals on the input side and the output side at a ground potential.

2. Related Art

Level shifters that convert a voltage level on the input side into another voltage level for outputting are used for various equipment. Because of the demand for power saving of various equipment in recent years, a reduction in power consumption is required also for level shifters.

As means to reduce the power consumption of level shifters, there are, for example, a method of holding an output signal of a level shifter at a predetermined level to thereby avoid an uncertain state, a method of preventing a shoot-through current from flowing, and so on. These methods are disclosed in, for example, JP-A-2005-102086.

In a configuration disclosed in JP-A-2005-102086, an output signal can be held at a predetermined level at the time of power down, irrespective of an input signal of a level shifter. However, in a configuration disclosed in, for example, FIG. 7 of JP-A-2005-102086, when an output signal (VPPSTP) goes Hi, the voltage of an input signal (VPPSTPF) becomes uncertain, allowing a shoot-through current to flow to an inverter (IV1) in some cases. Moreover, when the input signal is changed, a current flows between the input signal (VPPSTPF) and a ground potential (VSS) and between the ground potential (VSS) and a gate terminal (NDA) of a p-type transistor on the output side. When the current flows as described above, the power consumption in the level shifter is increased.

### SUMMARY

An advantage of some aspects of the invention is to provide a level shifter whose power consumption is reduced by preventing voltages at terminals on the input side and the output side from becoming uncertain.

An aspect of the invention is directed to a level shifter that converts an input signal changing between a first potential level and a second potential level into an output signal changing between the first potential level and a third potential level, including: a first circuit configured to be able to hold a potential at an input terminal to which the input signal is input at the first potential level; and a second circuit configured to be able to hold a potential at an output terminal from which the output signal is output at the first potential level.

According to the level shifter having the configuration, since the potentials at the input terminal and the output terminal can be held at the first potential level, changes in the input and output signals can be prevented at the time of power down. Thus, a current can be prevented from flowing because of the input and output signals brought into an uncertain state, and further the power consumption of the level shifter can be reduced. Moreover, since the input and output signals are fixed, a shoot-through current can be prevented from flowing because of an unintended change in the conductive state of transistors included in the level shifter. Thus, the power consumption of the level shifter can be reduced.

It is preferable that the first circuit is configured to include a first n-type semiconductor device connected between the input terminal and a first ground terminal, and that the second circuit is configured to include a second n-type semiconductor device connected between the output terminal and a second ground terminal.

According to the configuration, the first n-type semiconductor device and the second n-type semiconductor device are brought into the conductive state (on state), so that the input terminal and the output terminal can be held at the first potential level.

In comparison with the case where the input terminal and the output terminal are held at the first potential level using p-type semiconductor devices that are not turned on unless a gate voltage is −Vth or less, the circuit configuration is simple.

The first circuit may be configured to include a first resistance element connected between the input terminal and the first ground terminal, and the second circuit may be configured to include a second resistance element connected between the output terminal and the second ground terminal.

According to the configuration, it is possible to provide a level shifter that can hold the input signal and the output signal at the first potential level with a relatively simple configuration, which is advantageous in view of cost reduction, etc.

It is preferable that the level shifter includes the first n-type semiconductor device and the second n-type semiconductor device and is configured to stop the supply of voltage to the level shifter after bringing the first n-type semiconductor device and the second n-type semiconductor device into the conductive state.

According to the configuration, before stopping the supply of voltage to the level shifter, the potentials at the input terminal and the output terminal are held at the first potential level. Therefore, the potentials at the input terminal and the output terminal can be prevented from being brought into the uncertain state because of the stopping of voltage supply to the devices included in the level shifter.

It is preferable that the level shifter is configured to bring the potential of the input signal to the first potential level before bringing the first n-type semiconductor device and the second n-type semiconductor device into the conductive state.

According to the configuration, the potentials at the input terminal and the output terminal can be reliably held at the first potential level. Moreover, when the first n-type semiconductor device is brought into the conductive state, a leakage current can be prevented from flowing from the input terminal through the first n-type semiconductor device. Therefore, the power consumption of the level shifter can be reduced.

It is preferable that the level shifter includes the plurality of n-type semiconductor devices and is configured to start the supply of voltage to the level shifter, bring the first n-type semiconductor device and the second n-type semiconductor device into a non-conductive state after starting the supply of voltage to the level shifter, and start the input of the input signal to the input terminal after bringing the first n-type semiconductor device and the second n-type semiconductor device into the non-conductive state.

According to the configuration, at the time of powering on the level shifter, a change in the state of an unintended device can be prevented, or an unintended terminal can be prevented from being brought into the uncertain state. Therefore, the power consumption can be further reduced.

Another aspect of the invention is directed to a method of controlling a level shifter that converts an input signal changing between a first potential level and a second potential level into an output signal changing between the first potential level and a third potential level. The level shifter includes a first n-type semiconductor device connected between a first ground terminal and an input terminal to which the input signal is input, and a second n-type semiconductor device connected between a second ground terminal and an output terminal from which the output signal is output. The method includes, when stopping the supply of voltage to the level shifter, stopping the supply of voltage to the level shifter after bringing the first n-type semiconductor device and the second n-type semiconductor device into a conductive state.

According to the method, before stopping the supply of voltage to the level shifter, the input terminal and the output terminal are held at the first potential level. Therefore, the input terminal and the output terminal can be prevented from being brought into the uncertain state because of the stopping of voltage supply to the devices included in the level shifter.

### BRIEF DESCRIPTION OF THE DRAWINGS

The invention will be described with reference to the accompanying drawings, wherein like numbers reference like elements.

FIG. 1 shows a configuration example of a level shifter including n-type semiconductor devices.

FIG. 2 is a waveform chart showing the state of each part of the level shifter in operation.

FIG. 3 shows a configuration example of a power system including the level shifter.

FIG. 4 shows a configuration example of a level shifter including resistance elements.

### DESCRIPTION OF EXEMPLARY EMBODIMENTS

Embodiments according to the invention will be specifically described with reference to the drawings according to the following configuration. However, the embodiments described below are mere examples of the invention, and they are not intended to restrict the technical scope of the invention. Throughout the drawings, the same parts are denoted by the same reference numerals and signs, and the description thereof is sometimes omitted.

1. First embodiment
(1) Configuration example of level shifter
(2) Operation example of level shifter
(3) Configuration example of power system including level shifter

2. Second embodiment

3. Applicability of the invention

### 1. First Embodiment

The configuration and operation of a level shifter of the invention will be first described with reference to the drawings.

### (1) Configuration Example of Level Shifter

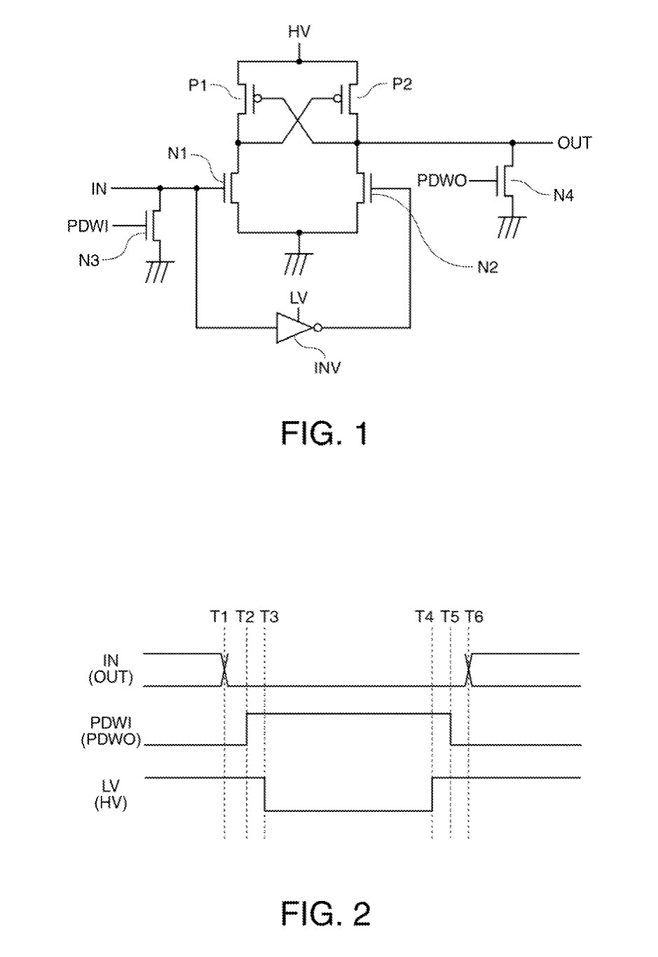

FIG. 1 shows the configuration of a level shifter in a first embodiment. As shown in FIG. 1, the level shifter is a circuit that converts a voltage level of an input signal IN and outputs the converted signal as an output signal OUT. The voltage level indicates a set of binary potentials, Hi and Lo, in a digital signal. For example, the voltage level indicates a set of potentials of a signal that goes to a first potential level as Lo level and goes to a second potential level as Hi level. Although a ground potential is selected as the first potential level in many cases, this is not restrictive. The level shifter is configured to include n-type transistors N1 to N4, p-type transistors P1 and P2, and an inverter INV.

A drain terminal of the n-type transistor N1 is connected to a gate terminal of the p-type transistor P2 and a drain terminal of the p-type transistor P1, and a source terminal of the n-type transistor N1 is connected to the ground potential. A gate terminal of the n-type transistor N1 is connected to an input terminal of the level shifter and a drain terminal of the n-type transistor N3. The n-type transistor N1 is configured such that the input signal IN is supplied thereto when the n-type transistor N3 is in a non-conductive state (off state).

A drain terminal of the n-type transistor N2 is connected to a gate terminal of the p-type transistor P1, a drain terminal of the p-type transistor P2, an output terminal of the level shifter, and a drain terminal of the n-type transistor N4. A source terminal of the n-type transistor N2 is connected to the ground potential. A gate terminal of the n-type transistor N2 is connected to an output terminal of the inverter INV. The n-type transistor N2 is configured such that the inverted signal of the input signal IN is supplied thereto.

An input terminal of the inverter INV is connected to the input terminal of the level shifter, and the output terminal of the inverter INV is connected to the gate terminal of the n-type transistor N2. As a voltage for driving the inverter INV, a first power supply voltage LV is supplied.

The n-type transistor N3 is connected between the ground potential and the input terminal of the level shifter to which the input signal IN is input. The n-type transistor N3 is configured such that a power-down signal PDWI is supplied to a gate terminal thereof.

The n-type transistor N4 is connected between the ground potential and the output terminal of the level shifter from which the output signal OUT is output. The n-type transistor N4 is configured such that a power-down signal PDWO is supplied to a gate terminal thereof.

A source terminal of the p-type transistor P1 is connected to a second power supply voltage HV, the drain terminal thereof is connected to the gate terminal of the p-type transistor P2 and the drain terminal of the n-type transistor N1. The gate terminal of the p-type transistor P1 is connected to the drain terminal of the p-type transistor P2, the drain terminal of the n-type transistor N2, the output terminal of the level shifter, and the drain terminal of the n-type transistor N4.

A source terminal of the p-type transistor P2 is connected to the second power supply voltage HV, and the drain terminal thereof is connected to the gate terminal of the p-type transistor P1, the drain terminal of the n-type transistor N2, the output terminal of the level shifter, and the drain terminal of the n-type transistor N4. The gate terminal of the p-type transistor P2 is connected to the drain terminal of the p-type transistor P1 and the drain terminal of the n-type transistor N1.

### (2) Operation Example of Level Shifter

An operation example of the level shifter shown in FIG. 1 will be next described with reference to FIG. 2. FIG. 2 is a waveform chart showing the state of each part of the level shifter in operation in the first embodiment.

In FIG. 2, at a time before time T1, the level shifter is in a power-on state where the level shifter is being driven. When the level shifter is brought into a power-down state, the input signal IN is first stopped at the time T1 and becomes a Lo level (ground potential level) signal. In this case as shown in FIG. 2, the output signal OUT indicates the same value as that of the input signal IN although being different in voltage level. Next, at time T2, the power-down signals PDWI and PDWO supplied to the gate terminals of the n-type transistors N3 and N4, respectively, are changed from the Lo level to the Hi level, so that both of the n-type transistors N3 and N4 are brought into a conductive state (on state). Thus, both of the input terminal and the output terminal are brought into a pull-down state where they are held at the ground potential. Next, at time T3, the supply of the first power supply voltage LV and the second power supply voltage HV to the level shifter is stopped.

When the supply of voltage to the level shifter is resumed or started to bring the level shifter into the power-on state, the supply of the first power supply voltage LV and the second power supply voltage HV to the level shifter is first started at time T4. Next, the signals PDWI and PDWO supplied to the gate terminals of the n-type transistors N3 and N4, respectively, are changed from the Hi level to the Lo level at time T5, so that both of the n-type transistors N3 and N4 are brought into the non-conductive state (off state). Thus, the input terminal and the output terminal are released from the pull-down state where they are held at the ground potential. Next, at time T6, the input of the input signal IN is resumed or started.

### (3) Configuration Example of Power System Including Level Shifter

A configuration example of a power system including the level shifter described so far will be next described.

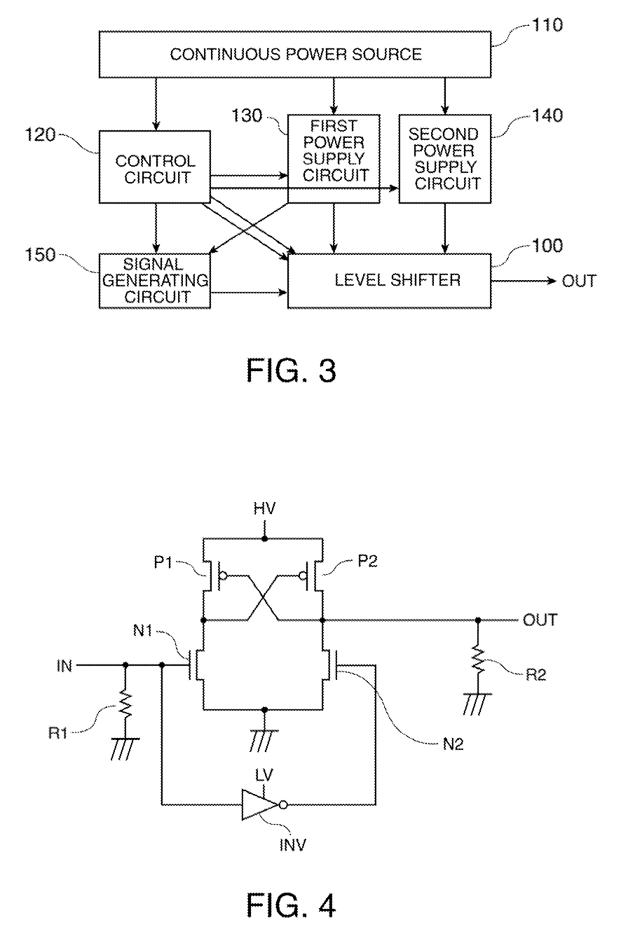

FIG. 3 shows a configuration example of a power system including the level shifter of the first embodiment. As shown in FIG. 3, the power system is configured to include the level shifter 100, a continuous power source (battery) 110, a control circuit 120, a first power supply circuit 130, a second power supply circuit 140, and a signal generating circuit 150.

The level shifter 100 is configured such that the first power supply voltage LV is input thereto from the first power supply circuit 130 and the second power supply voltage HV is input thereto from the second power supply circuit 140. Moreover, the level shifter 100 is configured to receive the power-down signals PDWI and PDWO from the control circuit 120 and receive the input signal IN from the signal generating circuit 150 to output the output signal OUT.

The continuous power source 110, which is a power source for the entire power system, is configured to supply a predetermined voltage to the control circuit 120, the first power supply circuit 130, and the second power supply circuit 140. Although the continuous power source 110 is composed of a battery or the like, this is not restrictive.

The control circuit 120 is configured to output control signals to the first power supply circuit 130, the second power supply circuit 140, and the signal generating circuit 150, and output the power-down signals PDWI and PDWO to the level shifter 100.

The control signal output to the first power supply circuit 130 by the control circuit 120 is a signal for controlling the starting and stopping of supply of the first power supply voltage LV given to the level shifter 100 by the first power supply circuit 130. The control signal output to the second power supply circuit 140 by the control circuit 120 is a signal for controlling the starting and stopping of supply of the second power supply voltage HV given to the level shifter 100 by the second power supply circuit 140. The control signal output to the signal generating circuit 150 by the control circuit 120 is a signal for generating the input signal IN. As has been described above, the power-down signals PDWI and PDWO output to the level shifter 100 by the control circuit 120 are signals for controlling the conductive state of the n-type transistors N3 and N4 included in the level shifter 100. The control circuit 120 is driven by a power supply voltage supplied from the continuous power source 110.

The first power supply circuit 130 is driven by a power supply voltage supplied from the continuous power source 110, boosts or lowers the power supply voltage as necessary to generate the first power supply voltage LV, and supplies the voltage to the signal generating circuit 150 and the level shifter 100.

The second power supply circuit 140 is configured to be driven by a power supply voltage supplied from the continuous power source 110, boost or lower the power supply voltage as necessary to generate the second power supply voltage HV, and supplies the voltage to the level shifter 100.

The signal generating circuit 150 is configured to generate the input signal IN based on the control signal input from the control circuit 120, and output the input signal to the level shifter 100. The signal generating circuit 150 is driven by the first power supply voltage LV supplied from the first power supply circuit 130.

According to the first embodiment, the following advantageous effects are provided. The level shifter of the first embodiment is a level shifter that converts the input signal IN changing between the first potential level and the second potential level into the output signal OUT changing between the first potential level and a third potential level. The level shifter includes the n-type transistor N3 configured to be able to hold the potential at the input terminal to which the input signal IN is input at the first potential level and the n-type transistor N4 configured to be able to hold the potential at the output terminal from which the output signal OUT is output at the first potential level. According to the level shifter having the configuration described above, the n-type transistors N3 and N4 are brought into the conductive state (on state), so that the input terminal and the output terminal can be held at the first potential level. Since the potentials at the input terminal and the output terminal can be held at the first potential level in this manner, unintended changes in the input signal IN and the output signal OUT can be prevented at the time of power down. Thus, a current can be prevented from flowing because of the input signal IN and the output signal OUT brought into the uncertain state, and further the power consumption of the level shifter can be reduced. Moreover, since the input signal IN and the output signal OUT are fixed, a shoot-through current can be prevented from flowing because of an unintended change in the conductive state of the transistors included in the level shifter. Thus, the power consumption of the level shifter can be reduced. Further, in comparison with the case where the input terminal and the output terminal are held at the first potential level using p-type semiconductor devices that are not turned on unless a gate voltage is −Vth or less, the circuit configuration is simple.

After the n-type transistors N3 and N4 are brought into the conductive state, the supply of voltage to the level shifter is stopped, whereby the input terminal and the output terminal can be held at the first potential level before stopping the supply of voltage to the level shifter. Therefore, it is possible to prevent the input terminal and the output terminal from being brought into the uncertain state because of the stopping of voltage supply to a device such as, for example, the inverter INV included in the level shifter.

Before the n-type transistors N3 and N4 are brought into the conductive state, the potential of the input signal IN is brought to the first potential level, whereby the potentials at the input terminal and the output terminal can be reliably held at the first potential level. Moreover, when the n-type transistor N3 is brought into the conductive state, a leakage current can be prevented from flowing from the input terminal through the n-type transistor N3. Therefore, the power consumption of the level shifter can be reduced.

At the time of powering on the level shifter, first the supply of voltage to the level shifter is started, then the n-type transistors N3 and N4 are brought into the non-conductive state, and finally the voltage supply to the input signal IN is started. Therefore, at the time of powering on the level shifter, a change in the state of an unintended device such as a transistor can be prevented, or an unintended terminal can be prevented from being brought into the uncertain state, which can further reduce the power consumption.

### 2. Second Embodiment

A second embodiment as another embodiment of the invention will be next described with reference to FIG. 4. In the second embodiment, the same configurations, functions, and operations as those of the first embodiment will not be described in detail.

FIG. 4 shows the configuration of a level shifter in the second embodiment. As shown in FIG. 4, the level shifter is configured to include the n-type transistors N1 and N2, the p-type transistors P1 and P2, the inverter INV, and resistance elements R1 and R2. When comparing the first embodiment with the second embodiment, the second embodiment differs from the first embodiment in that the resistance elements R1 and R2 are included instead of the n-type transistors N3 and N4 in the first embodiment, respectively. The difference will be specifically described below.

The resistance element R1 is connected between the ground potential and the input terminal of the level shifter to which the input signal IN is input. The resistance element R2 is connected between the ground potential and the output terminal of the level shifter from which the output signal OUT is output.

When the resistance element R1 is connected between the input terminal and the ground potential as described above, the potential of the input signal IN can be prevented from being brought into the uncertain state and can be held at the ground potential. The same applies to the output signal OUT.

According to the second embodiment, the following advantageous effects are provided. The level shifter of the second embodiment is a level shifter that converts the input signal IN changing between the first potential level and the second potential level into the output signal OUT changing between the first potential level and the third potential level. The level shifter includes the resistance element R1 configured to be able to hold the potential at the input terminal to which the input signal IN is input at the first potential level and the resistance element R2 configured to be able to hold the potential at the output terminal from which the output signal OUT is output at the first potential level. According to the level shifter having the configuration described above, the input terminal and the output terminal can be held at the first potential level. Since the potentials at the input terminal and the output terminal can be held at the first potential level in this manner, unintended changes in the input signal IN and the output signal OUT can be prevented at the time of power down. Thus, a current can be prevented from flowing because of the input signal IN and the output signal OUT brought into the uncertain state, and further the power consumption of the level shifter can be reduced. Moreover, since the input signal IN and the output signal OUT are fixed, a shoot-through current can be prevented from flowing because of an unintended change in the conductive state of the transistors included in the level shifter. Thus, the power consumption of the level shifter can be reduced. Further, the input signal and the output signal can be held at the first potential level with a simpler configuration than that of the level shifter according to the first embodiment, which is advantageous in view of cost reduction, etc.

### 3. Applicability of the Invention

The level shifter and the method of controlling the level shifter include not only the scope of the embodiments specifically described above but also an invention that may occur to those skilled in the art based on the scope.

That is, it is also possible to configure a level shifter in which one of or both of the n-type transistors N3 and N4 are replaced with p-type transistors.

Moreover, a form in which another device is connected in series to the n-type transistors N3 and N4 is also included in the invention.

Further, a form in which the first embodiment is combined with the second embodiment may be adopted. That is, it is also possible to connect the n-type transistor N3 and the resistance element R2 to the input terminal side and the output terminal side, respectively.

The entire disclosure of Japanese Patent Application No. 2010-086311, filed Apr. 2, 2010 is expressly incorporated by reference herein.

What is claimed is:

1. A level shifter that converts an input signal changing between a first potential level and a second potential level into an output signal changing between the first potential level and a third potential level, comprising:
a first circuit configured to be able to hold a potential at an input terminal to which the input signal is input at the first potential level; and
a second circuit configured to be able to hold a potential at an output terminal from which the output signal is output at the first potential level.

2. The level shifter according to claim 1, wherein
the first circuit is configured to include a first n-type semiconductor device connected between the input terminal and a first ground terminal, and
the second circuit is configured to include a second n-type semiconductor device connected between the output terminal and a second ground terminal.

3. The level shifter according to claim 1, wherein
the first circuit is configured to include a first resistance element connected between the input terminal and a first ground terminal, and
the second circuit is configured to include a second resistance element connected between the output terminal and a second ground terminal.

4. The level shifter according to claim 2, configured to stop the supply of voltage to the level shifter after bringing the first n-type semiconductor device and the second n-type semiconductor device into a conductive state.

5. The level shifter according to claim 4, configured to bring the potential of the input signal to the first potential level before bringing the first n-type semiconductor device and the second n-type semiconductor device into the conductive state.

6. The level shifter according to claim 2, configured to start the supply of voltage to the level shifter, bring the first n-type semiconductor device and the second n-type semiconductor device into a non-conductive state after starting the supply of voltage to the level shifter, and start the input of the input signal to the input terminal after bringing the first n-type semiconductor device and the second n-type semiconductor device into the non-conductive state.

7. A method of controlling a level shifter that converts an input signal changing between a first potential level and a second potential level into an output signal changing between the first potential level and a third potential level,
the level shifter including
a first n-type semiconductor device connected between a first ground terminal and an input terminal to which the input signal is input, and
a second n-type semiconductor device connected between a second ground terminal and an output terminal from which the output signal is output,
the method comprising:
when stopping the supply of voltage to the level shifter, stopping the supply of voltage to the level shifter after bringing the first n-type semiconductor device and the second n-type semiconductor device into a conductive state.
